(19) United States
(12) Patent Application Publication
(10) Pub. No.: US 2025/0284624 A1
(43) Pub. Date: Sep. 11, 2025

(54) Memory Architecture

(71) Applicant: Optalysys Ltd, Yorkshire (GB)

(72) Inventors: Iman KUNDU, Yorkshire (GB); Florent MICHEL, Yorkshire (GB)

(73) Assignee: Optalysys Ltd, Yorkshire (GB)

(21) Appl. No.: 18/851,991

(22) PCT Filed: Mar. 31, 2023
(86) PCT No.: PCT/GB2023/050873

§ 371 Date: Sep. 27, 2024

(30) Foreign Application Priority Data
Mar. 31, 2022 (GB) 2204750.0

(51) Int. Cl. G06F 12/02; G06F 7/78; G06F 13/16

(52) U.S. Cl. CPC G06F 12/0207; G06F 7/78; G06F 12/0246; G06F 13/1615

(57) ABSTRACT

A memory including: an array of memory cells; a memory access logic programmable to generate a write allocation that maps an input comprising elements of data in a first sequence to the memory cells of the array and a read allocation that maps the memory cells of the array to an output comprising elements of data in a second sequence; and a memory controller arranged to write the elements of data at the input to the array based on the write allocation and to read the elements of data stored in the array to the output based on the read allocation.

### FIELD

The present disclosure relates to a memory. It has particular, but not exclusive, applicability to a method and apparatus for a programmable, non-random access memory array, which may provide cell-based memory reading and writing.

### BACKGROUND

Memory architectures are crucial in reducing latency in intensive computing applications such as fully homomorphic encryption, Fourier transform and artificial intelligence.

Data stored in Random Access Memory (RAM) is typically organised in rows, and read/write operations usually occur over an entire row of data (consisting of multiple columns). Data throughput from RAMs can suffer from read/write conflicts, otherwise known as unrepeatable reads or reading uncommitted data. Uncommitted data is data which is being updated but has not yet been committed permanently back to the database. In other words, it is data upon which an update is occurring and the update has not yet been made permanent. In a memory architecture, a read/write conflict occurs when both read and write operations are attempted in the same location of the memory, so the write operation writes a value which makes the database inconsistent compared with the value that had been read by the read operation. This causes a lowering of processing rates in intensive computing tasks. Many conventional computer architectures suffer from limitations due to having fast processing capacity but slow memory access, known as a von Neumann bottleneck.

Register memories allow are fast memories that are typically used for buffering data. However, the capacity of register memories is limited. They are therefore only generally employed to hold frequently used data, instructions, and memory addresses, for easy access.

### SUMMARY

The invention is defined in the appended independent claims.

This overview introduces concepts that are described in more detail in the detailed description. It should not be used to identify essential features of the claimed subject matter, nor to limit the scope of the claimed subject matter.

The present disclosure describes a hybrid memory architecture which allows data to be stored discontinuously in arbitrary memory cell locations that are programmed and synchronised using a state machine controller and write-state counters. Similarly, data is read from arbitrary memory cell locations, which are determined using a similar program and synchronised by another state machine controller and read-state counters. A state machine controller is a controller that can be a finite number of different conditions, where a state machine is a behaviour model that can be called a Finite State Machine (FSM). The memory architecture also includes an in-memory compute logic that permits simple arithmetic operations (such as addition, two's complement conversion, increment, decrement and bit-shifting) and logic operations (such as AND, OR, XOR, NOR, NAND) on the data. The in-memory compute logic allows the occurrence of arithmetic and logic operations on the data stored on the memory cells and reduces latency.

The present disclosure provides a memory comprising: an array of memory cells; a memory access logic programmable to generate a write allocation that maps an input comprising elements of data to the memory cells of the array and a read allocation that maps the memory cells of the array to an output comprising elements of data; and a memory controller arranged to write the elements of data at the input to the array based on the write allocation and to read the elements of data stored in the array to the output based on the read allocation.

There is therefore provided, a memory comprising: an array of memory cells; a memory access logic programmable to generate a write allocation that maps an input comprising elements of data in a first sequence to the memory cells of the array and a read allocation that maps the memory cells of the array to an output comprising elements of data in a second sequence; and a memory controller arranged to write the elements of data at the input to the array based on the write allocation and to read the elements of data stored in the array to the output based on the read allocation.

Optionally, the first sequence is different to the second sequence such that a first sequence order of the elements of data at the input is different to a second sequence order of the elements of data at the output.

Optionally, the input is a parallel input of a first width and the output is a parallel output of a second width, preferably wherein the first and second widths are the same.

Optionally, the memory access logic is configured to be reprogrammed to generate different write and read allocations.

Optionally, the elements of data at the input and output are one of: single bits of a data word or multi-bit words of a data string.

Optionally, the most significant to least significant bit or word of each single bit or multi-bit word is mapped to the input or read to the output in parallel.

Optionally, the write allocation maps the input to respective first subsets of the memory cells of the array in a first subset order, and the read allocation reads respective second subsets of the memory cells to the output in a second subset order.

Optionally, the first subsets each comprise a respective first arrangement of memory cells of the array and the second subsets each comprise a respective second arrangement of memory cells of the array.

Optionally, each of the respective first arrangements are different to each of the respective second arrangements.

Optionally, the first arrangements each have a width equal to a/the first width of the input and a/the second width of the output.

Optionally, the first and second arrangements each have a width equal to a/the first width of the input and a/the second width of the output.

Optionally, the first subset order is different to the second subset order.

Optionally, each of the first subsets comprise a row or a column of the memory cells of the array.

Optionally, each of the first subsets comprise a row of the memory cells of the array.

Optionally, each of the first subsets comprise a column of the memory cells of the array.

Optionally, each of the second subsets comprise a row or a column of the memory cells of the array.

Optionally, each of the second subsets comprise a row of the memory cells of the array.

Optionally, each of the second subsets comprise a column of the memory cells of the array.

Optionally, each of the first subsets of the memory cells of the array are adjacent such that the input is mapped to respective first subsets of adjacent memory cells of the array, and each of the second subsets of the memory cells of the array are adjacent such that the output is read from respective second subsets of adjacent memory cells of the array.

Optionally, each single bit or multi-bit word is mapped to respective first subsets of adjacent memory cells of the array, and each single bit or multi-bit word is read to the output from respective second subsets of adjacent memory cells of the array.

Optionally, the second subset order of the memory cells of the array read to the output is a predetermined shift of the first subset order of the memory cells of the array.

Optionally, the second subset order of the memory cells of the array read to the output is a rotation of the first subset order of the memory cells of the array.

Optionally, the first subset order is a butterfly transposition of the elements of data at the input.

Optionally, each respective first subset of the memory cells of the array and each respective second subset of the memory cells of the array both comprise at least one single bit from each data word or at least one multi-bit word from each data string at the input.

Optionally, each row or column of the memory cells of the array of the first subset comprises a plurality of multi-bit words of one data string of a plurality of data strings at the input, and wherein each respective second subset of the memory cells of the array comprises at least one multi-bit word from each data string of the plurality of data strings at the input.

Optionally, the memory access logic comprises a read logic and a write logic, wherein the read logic generates the read allocation and the write logic generates the write allocation.

Optionally, the memory access logic comprises: a read state controller; and a write state controller.

Optionally, the memory further comprising a memory interface configured to transfer the elements of data at the input to the memory cells of the array and to transfer the elements of data stored in the memory cells of the array to the output.

Optionally, memory interface comprises a read data bus, and a write data bus, wherein read and write data buses are configured to transfer instructions for programming the memory access logic to the memory access logic.

Optionally, the read and write data buses are further configured to supply the memory access logic with a read counter, a write counter and a status control.

Optionally, the read and write state controllers configured to use the read and write counters and the status to set, reset, read or write both data and sequence counters within the memory access logic.

Optionally, the memory further comprising a data allocator switch fabric configured to connect the memory cells with the memory access logic and the memory controller.

Optionally, the data allocator switch fabric comprises a switch fabric, a read data allocator and a write data allocator, wherein the read and write data allocators are configured to decode an address of the array corresponding to the read allocation or the write allocation.

Optionally, the switch fabric is mapped to the bus size according to the bit numbering of individual data.

Optionally, the memory cells of the array are divided into a first memory cell subgroup and a second memory cell subgroup; the input comprises a first input frame and a second input frame; the first input frame comprises a first data element and second data element; the second input frame comprises a third data element and a fourth data element.

Optionally, the write allocation maps: the first data element to a first memory cell in the first memory cell subgroup; the second data element to first memory cell in the second memory cell subgroup; the third data element to a second memory cell of the first memory cell subgroup; and the fourth data element to a second memory cell of the second memory cell subgroup.

Optionally, a transformational relationship between the location of the first memory cell and second memory cell in the first memory cell subgroup corresponds to or is identical to a transformational relationship between the location of the first memory cell and second memory cell in the second memory cell subgroup.

Optionally, the transformational relationship is a translational or a rotational relationship, optionally wherein the transformational relationship is to rotate or translate by a single memory cell from one memory cell to an adjacent memory cell.

Optionally, the order of the first data element in the first input frame corresponds with the order of the third data element in the second input frame, and the order of the second data element in the first input frame corresponds with the order of the fourth data element in the second input frame.

Optionally, the read allocation maps the memory cells of the array to an output comprising a first output frame comprising the first data element and the third data element and a second output frame comprising the second data element and the fourth data element.

Optionally, the order of the first data element in the first output frame corresponds with the order of the second data element in the second output frame.

Optionally, the order of the third data element in the first output frame corresponds with the order of the fourth data element in the second output frame.

Optionally, the first input frame and second input frame each include data corresponding to detected light intensity values at an output plane of an optical Fourier transform stage.

Optionally, each of the first and second data elements corresponds to a detected light intensity value at a port in an array of ports at an output plane of an optical Fourier transform stage, and wherein each of the third and fourth data elements corresponds to a detected light intensity value at a port in an array of ports at an output plane of the same or another optical Fourier transform stage.

Optionally, the relative order of the first and second data elements in the first input frame and the relative order of the third and fourth data elements in the second input frame each correspond to a relative position of ports in an array of ports at an output plane in the respective optical Fourier transformation stage, optionally wherein the relative order is adjacent or subsequent positions in an order and the relative position is an adjacent position in the array of ports.

Optionally, the first data element corresponds to a first detected intensity at a first port in an array of ports at an output plane of an optical Fourier transform stage and the third data element corresponds to a second detected intensity at the first port.

Optionally the second data element corresponds to a third detected intensity at a second port in the array of ports and the fourth data element corresponds to a fourth detected intensity at the second port.

There is also provided, a method comprising: generating, in a memory access logic, a write allocation that maps an input to memory cells of an array of memory cell in a first sequence and a read allocation that maps the memory cells of the array to an output in a second sequence; writing elements of data at the input to the array based on the write allocation; and reading elements of data stored in the array to the output based on the read allocation.

### BRIEF DESCRIPTION OF THE DRAWINGS

Specific embodiments are described below by way of example only and with reference to the accompanying drawings in which:

FIGS. 1A-1B are examples of repositioning data using a butterfly transposition;

FIG. 2 is an example of repositioning data using a rotation;

FIG. 3 is an example of repositioning data using a shift;

FIG. 4 shows a memory comprising key features;

FIGS. 5A-5B are example embodiments of the memory architecture and memory access logic;

FIG. 6 is an example embodiment of the memory architecture and memory access logic;

FIG. 7 is an example state diagram of the memory architecture; and

FIGS. 8A-8B are examples of reading and writing data to the memory.

In the Figures, like reference numerals refer to like parts.

### DETAILED DESCRIPTION

Re-ordering of data or data transposition is useful in intensive computation, such as fully homomorphic encryption (FHE), Fourier transform (FT) and convolution neural network (CNN) based artificial intelligence (AI) operations. Using existing memory architectures, data needs to be moved multiple times, or held in expensive register memories to facilitate demanding re-ordering of data or transpositions. Moreover, with the emergence of optical and photonic computing, where photons are used to perform mathematical operations, memory access and latency become even more important due to the fast operation inherent to optical and photonic computing.

Optical Fourier transform (OFT) can calculate an FT in a single clock cycle. In order to calculate large FTs of any dimension and accuracy, native OFT data needs to be re-ordered or transposed in memory. Performing such operations in a traditional (SRAM/DRAM/cache or register) memories would need numerous data shifts and multiple passes of data read and write. For high performance computing applications and workflows this is a significant bottleneck and introduces latency which slows the overall performance of the computation. In systems where processing occurs at much faster speeds than memory access speeds, such as optical computing, transposing the data in a data shift is particularly prevalent. In such systems the processing speeds are limited by the memory access speeds.

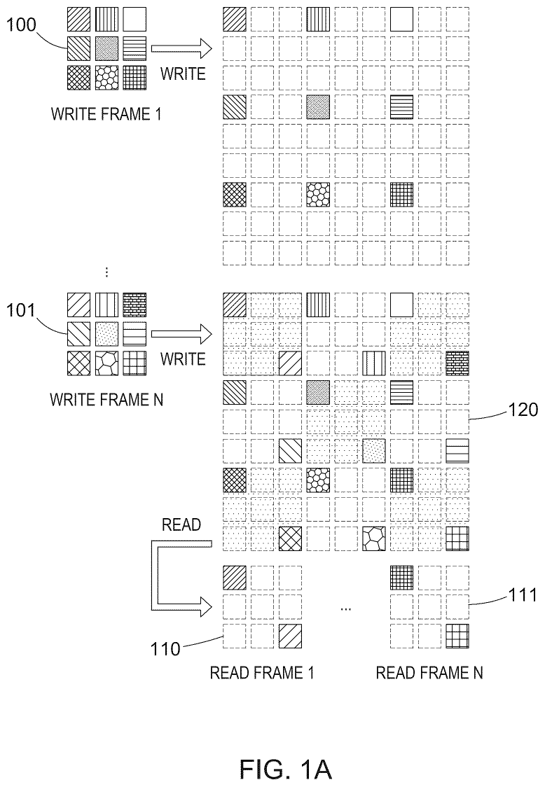

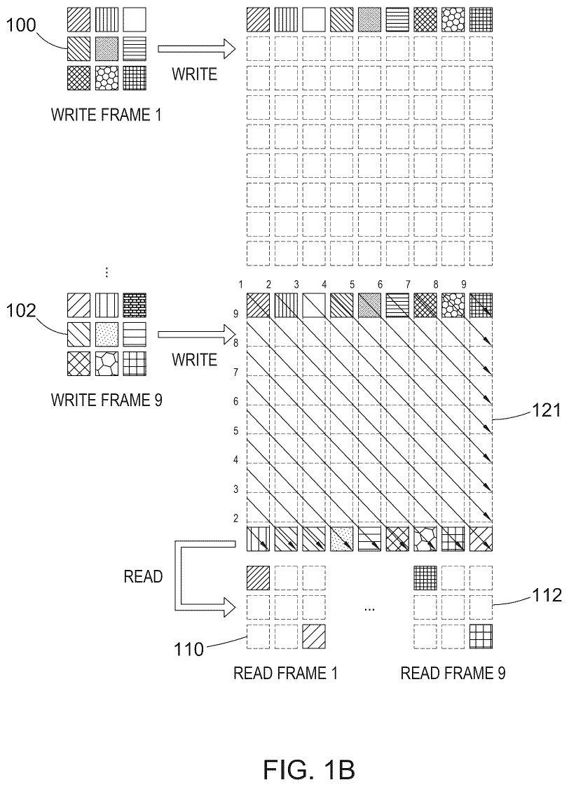

In each of FIGS. 1A-3, the input of the example memory architectures may be a parallel input of a first width and the output may be a parallel output of a second width. The width of the input or output refers to the amount of bits or words. A write allocation maps the input to respective first subsets of the memory cells of the array in a first subset order, and the read allocation reads respective second subsets of the memory cells to the output in a second subset order. In each of FIGS. 1a-3, the first subset order is different to the second subset order.

In OFT, native FT data needs to be fragmented, re-ordered or transposed and written to memory. Native FT data can be called an input, or elements of data, or elements of data in a first sequence, or a frame, or a native FT frame, which consists of a FT of a given size, either one-dimensional (1D) or two-dimensional (2D), and is determined by the native resolution of a photonic core of the photonic device in use. An example of data re-ordering is shown in FIG. 1A, where an input 110, 111 comprises elements of data in a first sequence or in other words, native FT frames 110, 111 comprise a plurality of data points. Multiple native FT frames 100, 101 (WRITE FRAME 1, . . . , WRITE FRAME N) are successively reordered or transposed according to a pre-defined mapping. The pre-defined mapping is programmed by a memory access logic which generates a write allocation and a read allocation. The write allocation maps the input 110, 111 comprising elements of data in a first sequence (or native FT frames 110, 111 comprising a plurality of data points) to the memory cells of an array 120 and the read allocation maps the memory cells of the array 120 to an output 110, 111 comprising elements of data in a second sequence (or the reordered or transposed native FT frames 110, 111). In this embodiment, first sequence is different to the second sequence such that a first sequence order of the elements of data at the input is different to a second sequence order of the elements of data at the output, however, it is possible for the first and second sequences to be the same. This mapping may be butterfly re-ordering used in the calculation of fast FT (FFT). A memory controller writes the elements of data at the input to the array 120 based on the write allocation and reads the elements of data stored in the array 120 to the output based on the read allocation. The write allocation may map the input 100, 101 to respective first subsets of the memory cells of the array 120 in a first subset order, and the read allocation may read respective second subsets of the memory cells of the array 120 to the output 110, 111 in a second subset order. The first subset order is different to the second subset order. The first subsets each comprise a respective first arrangement of memory cells of the array 120 and the second subsets each comprise a respective second arrangement of memory cells of the array 120. Each of the respective first arrangements are different to each of the respective second arrangements. A first width of the input 100, 101 and a second width of the output 110, 111 are the same. The first and second arrangements each have a width equal to the first width of the input 100, 101 and the second width of the output 110, 111.

The butterfly re-ordering logic may be programmed using a dedicated Instruction Set Architecture (ISA) via a processor, or a microcontroller, or a co-processor, or a secondary host, or another similar logic circuit. In the illustrated embodiment, each native FT frame 100, 101 comprises 9 data points which represent an array, or more specifically, a 2D array, or even more specifically, a 2D mathematical array. The total dataset comprising 9×9 data points where each frame contains 3×3 subsets of the total array is processed. Moreover, each of the 9 native FT frames form a logical constellation of 3×3 frames, or a 3×3 subset, i.e. a total dataset of 9×9 data points is processed where each frame contains a 3×3 subset of the total array. Each of the data points is shown in a different shade which is shown for differentiation purposes only. According to a predefined logic, incoming frames comprising native FT data 100, 101 are fragmented or re-ordered such that each data point in the array 120 is offset by 2 positions (one horizontal and one vertical) relative to their original position in the array and the frame number. This is repeated for N=9 frames, such that the data from all 9 frames are transposed to form an array of 9×9 data points.

As can be seen in FIG. 1A and described above, the array, or total dataset 120 of 9×9 data points, can be seen as a logical arrangement of nine 3×3 memory cell subgroups, where a first, second and third memory cell subgroups form a first row of the total dataset, a fourth, fifth and sixth memory cell subgroups form a second row of the total dataset, and a seventh, eighth and ninth memory cell subgroups form a third row of the total dataset. In this manner, the first, fourth and seventh memory cell subgroups form a first column of the total dataset, the second, fifth and eighth memory cell subgroups form a second column of the total dataset and the third, sixth and ninth memory cell subgroups form a third column of the total dataset. The write allocation maps each input frame to a respective first subset of the memory cells of the array (the first to ninth memory cell subgroups) in a first subset order. Each of the data points in a first frame 100 (WRITE FRAME 1) are re-ordered or transposed such that they are in the position of row 1, column 1 in each respective memory cell subgroup. The data is simultaneously written to each position from left to right, writing to the first row of the total dataset, the second row of the total dataset, the third row of the total dataset. For example, the data point in row 1, column 1 of the first frame gets transposed to row 1, column 1 of the first memory cell subgroup, the data point in row 1, column 2 of the first frame gets transposed to row 1, column 1 of the second memory cell subgroup, the data point in row 1, column 3 of the first frame gets transposed to row 1, column 1 of the third memory cell subgroup, the data point in row 2, column 1 of the first frame gets transposed to row 1, column 1 of the fourth memory cell subgroup, the data point in row 2, column 2 of the first frame gets transposed to row 1, column 1 of the fifth memory cell subgroup, the data point in row 2, column 3 of the first frame gets transposed to row 1, column 1 of the sixth memory cell subgroup, the data point in row 3, column 1 of the first frame gets transposed to row 1, column 1 of the seventh memory cell subgroup, the data point in row 3, column 2 of the first frame gets transposed to row 1, column 1 of the eighth memory cell subgroup, the data point in row 3, column 3 of the first frame gets transposed to row 1, column 1 of the ninth memory cell subgroup. Row 1, column 1 may be called a first position, row 1, column 2 may be called a second position, row 1, column 3 may be called a third position, row 2, column 1 may be called a fourth position, row 2, column 2 may be called a fifth position, row 2, column 3 may be called a sixth position, row 3, column 1 may be called a seventh position, row 3, column 2 may be called an eight position, row 3, column 3 may be called a ninth position. Each of the data points in a second frame get transposed in the same manner, but to a second position of each respective memory cell subgroup. It can be said that each of the data points in a first to N^{th} frame get transposed to a first to N^{th} position of each respective memory cell subgroup of the total dataset in the first subset order.

Once all of the data points from the native FT frames 100, 101 (WRITE FRAME 1, . . . , WRITE FRAME N) have been transposed and the total dataset 120 is ready for processing, the total dataset 120 is logically partitioned into many individual frames 110, 111 (READ FRAME 1, . . . , READ FRAME N) shown as alternate grey and white squares in FIG. 1A, and read from the memory for further processing by the read allocation which reads respective second subsets 110, 111 of the memory cells to the output in a second subset order. As previously described, in this embodiment the total dataset 120 can be seen as nine 3×3 memory cell subgroups so each of the individual read frames is the first to ninth memory cell subgroups. In this case the first to ninth memory cells subgroups correspond to first to nth read frames defined herein as second subsets (READ FRAME 1, . . . , READ FRAME N). If the elements of data at the input 110, 101 and output 110, 111 are one of: single bits of a data word or multi-bit words of a data string, then each respective first subset of the memory cells of the array 120 and each respective second subset of the memory cells of the array 120 both comprise at least one single bit from each data word or at least one a multi-bit word from each data string at the input. In this manner, the first subset order is a butterfly transposition of the elements of data at the input.

The embodiment described in relation to FIG. 1A can be described in more general terms as follows. The memory cells of the array are divided into a first memory cell subgroup and a second memory cell subgroup; the input comprises a first input frame (or write frame) and a second input frame (or write frame); the first input frame comprises a first data element and second data element; and the second input frame comprises a third data element and a fourth data element. Here, the write allocation maps: the first data element to a first memory cell in the first memory cell subgroup; the second data element to first memory cell in the second memory cell subgroup; the third data element to a second memory cell of the first memory cell subgroup; and the fourth data element to a second memory cell of the second memory cell subgroup.

A transformational relationship between the location of the first memory cell and second memory cell in the first memory cell subgroup corresponds to or is identical to a transformational relationship between the location of the first memory cell and second memory cell in the second memory cell subgroup.

The transformational relationship can be a translational or a rotational relationship. Optionally, the transformational relationship is to rotate or translate by a single memory cell from one memory cell to an adjacent memory cell, but the disclosure is not limited thereto and other transformations are envisaged.

The order of the first data element in the first input frame corresponds with the order of the third data element in the second input frame, and the order of the second data element in the first input frame corresponds with the order of the fourth data element in the second input frame.

The read allocation maps the memory cells of the array to an output comprising a first output frame (or read frame) comprising the first data element and the third data element and a second output frame (or read frame) comprising the second data element and the fourth data element.

The order of the first data element in the first output frame may correspond with the order of the second data element in the second output frame. The order of the third data element in the first output frame may correspond with the order of the fourth data element in the second output frame.

The first input frame and second input frame each include data corresponding to detected light intensity values at an output plane of an optical Fourier transform stage.

In some implementations, the memory is read by reading the data in the memory cell subgroups one subgroup at a time (optionally, but not necessarily, in the order in which the data appears in the memory cell subgroups), wherein one read frame corresponds to one memory cell subgroup. In other implementations, the read frames may each sample data from different memory cell subgroups and/or may sample a subset of the data from one memory cell subgroup.

It may be understood that these general principles (and by analogy, the embodiments described herein, including, for example, the embodiments described with reference to FIGS. 1A and 1B) may be applied to commit (write) to memory output frames of an OFT stage or OFT device. The type of OFT device in question is one which performs an optical Fourier transform of an optical input function. The optical output (Fourier transform) function is derived by sampling an interference pattern at the Fourier plane of the OFT stage or device. The sampling may be performed by using detectors distributed in an array. The detectors may detect light collected at an array of output ports positioned in the Fourier plane. A frame may be considered to be a snapshot either the full OFT or a sample thereof. A frame of the output of the OFT device would correspond to one of the (e.g. aforementioned first and second) input frames to the memory cells (i.e. one of the write frames). Alternatively, multiple write frames may correspond to (or sample different regions or areas of) a single optical Fourier transform output frame.

In particular, following on from the more generalised description of the principles exemplified in FIG. 1A, the first and second input frames may be a detected light intensity value at a port in an array of ports at an output plane of an optical Fourier transform stage, and each of the third and fourth data elements corresponds to a detected light intensity value at a port in an array of ports at an output plane of the same or another optical Fourier transform stage.

The relative order of the first and second data elements in the first input frame and the relative order of the third and fourth data elements in the second input frame each correspond to a relative position of ports in an array of ports at an output plane in the respective optical Fourier transformation stage, optionally wherein the relative order is adjacent or subsequent positions in an order and the relative position is an adjacent position in the array of ports.

In this sense, it may be said that the first data element corresponds to a first detected intensity at a first port in an array of ports at an output plane of an optical Fourier transform stage and the third data element corresponds to a second detected intensity at the first port. The second data element corresponds to a third detected intensity at a second port in the array of ports and the fourth data element corresponds to a fourth detected intensity at the second port. In other words, the first and second input frames sample different frames of the optical Fourier transform so that two different optical Fourier transform functions (or samples thereof) can be written to memory.

FIG. 1B shows a similar embodiment to FIG. 1A and is a further example of how the generalised principles set out above can be implemented. In FIG. 1B, the memory cell subgroups are not defined by the 9×9 arrays as in FIG. 1A but are defined by diagonal rows of memory cells as denoted by the numbers 1-9 and arrows in FIG. 1B. Applying the generalised description above to FIG. 1B, the first memory cell subgroup is the group of memory cells denoted by the diagonal arrow labelled with the numeral 1. The second memory cell subgroup is the group of memory cells denoted by the diagonal arrow labelled with the numeral 2 (including the cell in row 9, column 1) etc. Then, the first memory cell of the first memory cell subgroup is the cell in row 1, column 1; the first memory cell of the second memory cell subgroup is the cell in row 1, column 2; the second memory cell of the first memory cell subgroup is the cell in row 2, column 2; and the second memory cell of the second memory cell subgroup is the cell in row 2, column 3.

In another aspect of FIG. 1B, instead of each respective first subset of the memory cells of the array 120 and each respective second subset of the memory cells of the array 120 both comprising at least one single bit from each data word or at least one a multi-bit word from each data string at the input, each of the first subsets comprise a row of the memory cells of the array, the first subsets comprising multi-bit words of one data string of a plurality of data strings. Therefore, each row of the memory cells of the array of the first subset in FIG. 1B comprises a plurality of multi-bit words of one data string of a plurality of data strings at the input, and wherein each respective second subset of the memory cells of the array comprises at least one multi-bit word from each data string of the plurality of data strings at the input.

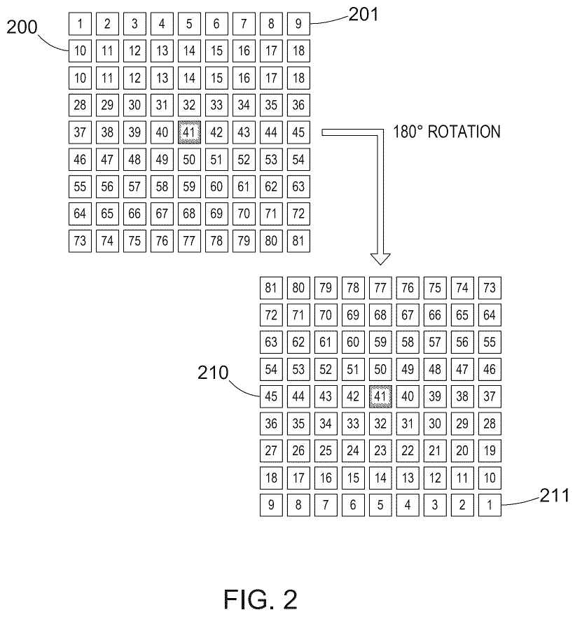

Turning to FIG. 2, another transposition of data useful in OFT processing can be seen. In this embodiment, data is rotated and more specifically, the data points are shuffled akin to a left/right rotation. Each of the first and second subsets comprise a row or a column of the memory cells of the array, in this embodiment, the first and second subsets each comprise a row of the memory cells of the array. As described above, a write allocation maps the input to respective first subsets of the memory cells of the array in a first subset order 200, and the read allocation reads respective second subsets of the memory cells to the output in a second subset order 210. The second subset order of the memory cells of the array read to the output of FIG. 2 is a rotation of the first subset order of the memory cells of the array. In this embodiment, the array 200 is re-ordered or transposed such that the data points are rotated, in this example about a central data point (numbered 41) and by 180 degrees. In this manner, the first row 201 of the array or incoming frame 200 comprises data points 1-9, seen from column 1 to column 9. In the transposed array or transposed frame 210, the data points 1-9 are on the ninth row 211 (in reverse order), seen from column 9 to column 1. The first subsets each comprise a respective first arrangement of memory cells of the array and the second subsets each comprise a respective second arrangement of memory cells of the array. Each of the respective first arrangements are different to each of the respective second arrangements.

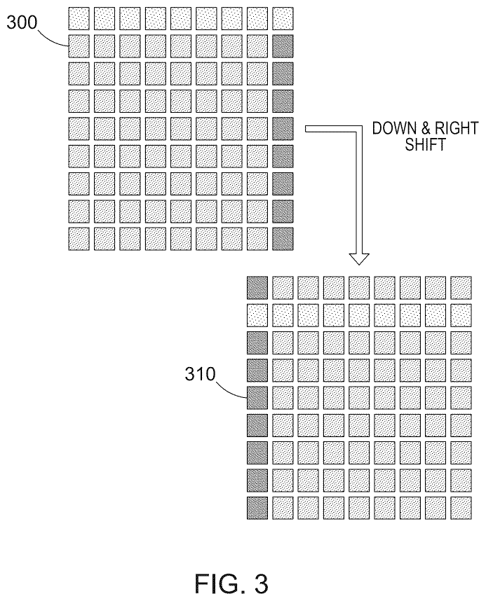

FIG. 3, shows a another transposition of ordered data by a memory architecture and memory access logic, which can be programmed using dedicated read/write access logic built into a memory driver circuit. An arithmetic and logic unit (ALU) may also be integrated into the memory driver enabling in-memory computing and logic operations on data. The in-memory computing occurs on the transposed data during read/write operations in the memory. In this embodiment, the first and second subsets each comprise a row or a column of the memory cells of the array. The second subset order of the memory cells of the array read to the output is a predetermined shift or an arbitrary shift of the first subset order of the memory cells of the array. The first subsets each comprise a respective first arrangement of memory cells of the array and the second subsets each comprise a respective second arrangement of memory cells of the array. Each of the respective first arrangements are different to each of the respective second arrangements. The data points in the 9×9 array 300 seen in FIG. 3 are shifted down one row and right one column to output the transposed array 310.

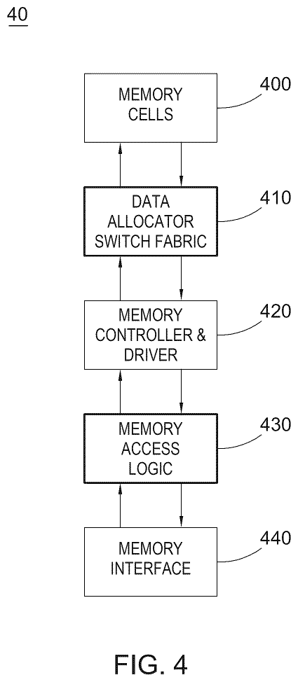

The memory 40 is useful for the transposition of ordered data and can be considered as having five key elements, as described with reference to FIG. 4. Memory cells 400 comprise an array of memory cells. The memory cells 400 store the data. A data allocator switch (or switching) fabric 410 allows parallel read/write data transfer between the memory cells 400 and a memory controller and driver 420. Generally, the data allocator switch fabric 410 controls traffic between two nodes/ports and is a combination of hardware and software. The data allocator switch fabric 410 may comprise read and write data allocators and a fabric which may act as a switch or more specifically, a switch and multiplexing/demultiplexing network. The data allocator switch fabric 410 allows data transfer reads and writes to occur at a higher rate than other memory architectures. It allows dynamic allocation, so increases the flexibility of determining network throughput. The memory controller and driver 420 (or memory controller and driver circuit) writes and reads data to and from the memory cells 400. A memory access logic 430 processes access control instructions to regulate access to the memory, and controls the sequence in which memory requests (from a memory interface 440) are serviced by the memory controller and driver 420. The memory interface 440 interfaces the memory 40 with a read and a write bus, the read and write buses both respectively carrying the instructions to program, control and access the memory 40. The write bus carries data to the memory 40 and the read bus carries data from the memory 40.

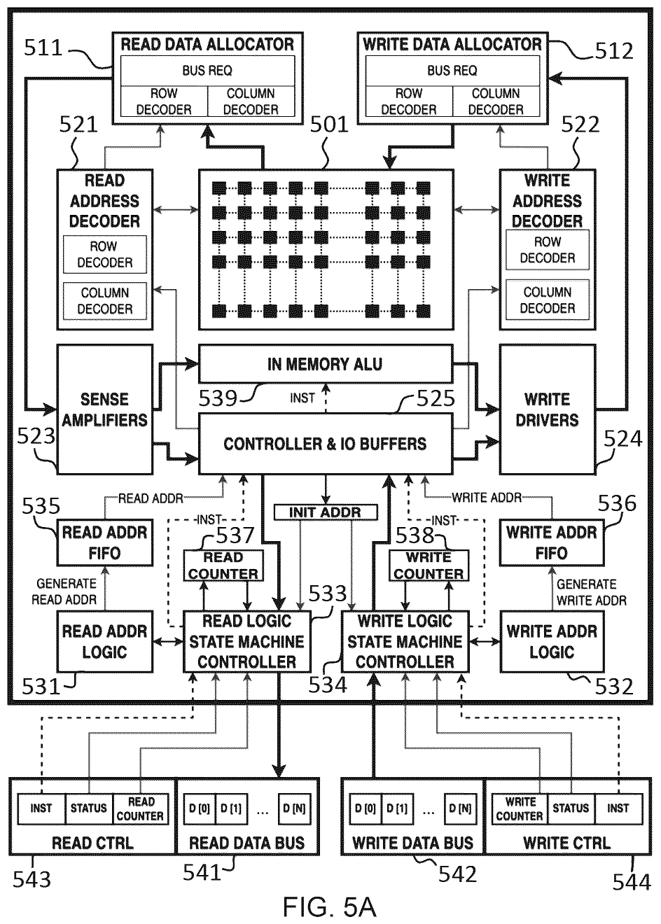

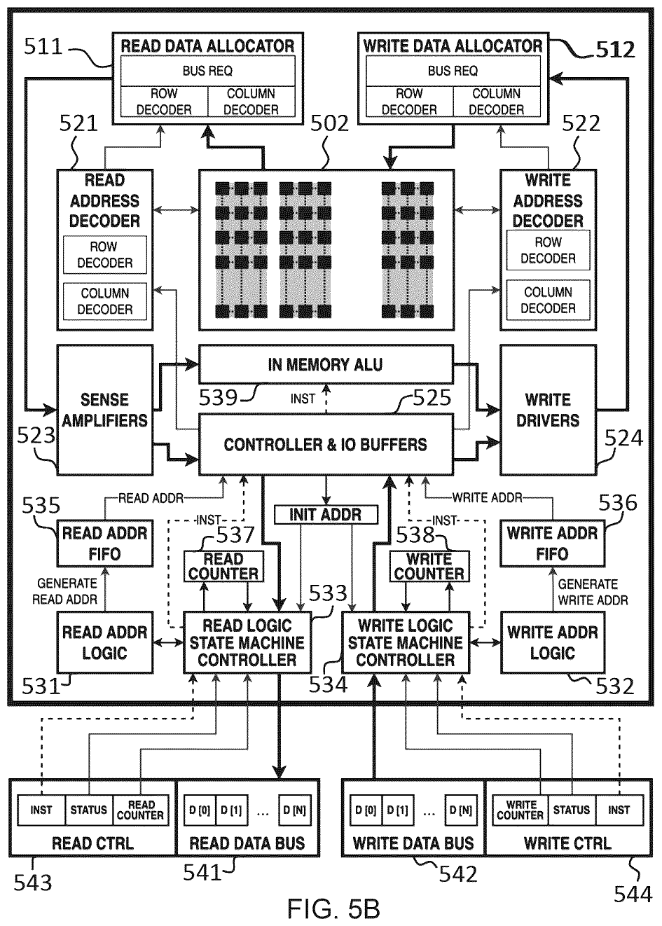

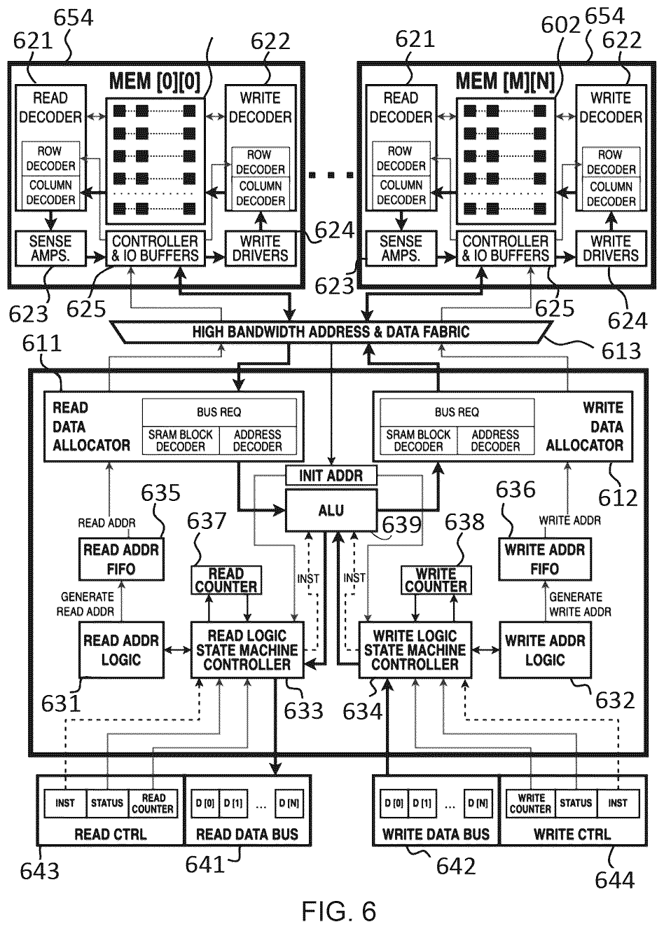

The details of some aspects of the memory 40, such as the memory access logic 430 and the architecture of the memory cells 400, depend on the size of the data that needs transposition, i.e. if the data is single-bit or multi-bit. When the data for transposing and processing is single bit data as shown in FIG. 5A where single bits of data words or bits of a multi-bit word from a data string are transposed, data transposition occurs on a bit level so each bit is transposed individually. When the data for transposing and processing is multi-bit data forming multi-bit words as part of data strings as shown in FIG. 5B and FIG. 6, data transposition occurs on multi-bit words so each word is transposed individually to ensure each word remains unchanged. In the embodiment of FIG. 5B, the single-bit unit cell of FIG. 5A is replaced with multi-bit cells and the data allocator switch fabric 410 is a multi-dimensional switch network permitting multi-bit parallel data transfer between each multi-bit cell and the controller circuit. In the embodiment of FIG. 6, multiple memory blocks with a width equal to the width of the multi-bit words is provided. As a plurality of memory blocks are required, the data allocator switch fabric may be a wide bus permitting parallel data transfer between the memory access logic and multiple memory blocks.

FIGS. 5A, 5B and 6 all show example embodiments of the memory architecture and memory access logic. FIG. 5A shows an embodiment of storing and reading/writing single bits, whereas FIGS. 5B and 6 show an embodiment of storing and reading/writing multi-bit words. Each of FIGS. 5A, 5B and 6 comprise the elements as described with reference to FIG. 4 and will be described in general terms that cover both embodiments.

### Memory Cells

The memory cells 400 may comprise any traditional memory cell.

### Data Allocator Switch Fabric

The data allocator switch fabric 410 acts as a bridge between the memory cells 400, the memory controllers and driver 420, and the memory access logic 430. The data allocator switch fabric 410 decodes the address (or location) of the memory cells 400 and opens a channel in the data allocator switch fabric 410, connecting the memory cells 400 with the memory controller and driver 420, through which data is transferred to and from memory cells 400. The data allocator switch fabric 410 aids in moving data that is being transferred to and from memory cells 400, where the data allocator switch fabric 410 is the interconnecting architecture between connection points or nodes. In the current embodiments the connection points are the memory cells 400, the memory controllers and driver 420 and the memory access logic 430. The channel in the data allocator switch fabric 410 ensures that the data can be transferred to or from the correct place, e.g. the memory cells 400, the memory controllers and driver 420 or the memory access logic 430. The use of the data allocator switch fabric 410 and the memory access logic 430 ensures that read/write collisions are avoided. The data allocator switch fabric 410 in the present embodiments comprises a read data allocator and a write data allocator. This is because the data allocator switch fabric 410 decodes the address of the cell of the memory cells 400 required for the data to be transferred to/from while the memory access logic 430 controls read/write access to the memory cells 400. The decoding scheme of the data allocator switch fabric 410 depends on the size of the data that needs to be re-ordered or transposed. The decoding schemes can be described with reference to any of FIGS. 5A, 5B and 6.

### Transposition and Processing of Single-Bit Data

When the data requiring re-ordering or transposition is a data word with a single bit, the memory cells 400 are designed such that each cell in the memory has an unique address. Each of the memory cells are connected to the read/write data allocators via an M-dimension fabric, where M is the width of the data bus. The width of the data bus refers to the maximum amount of data that can be transferred by the bus, or the number of bits that make up the bus. Therefore, the size of the fabric depends on the amount of bits in the data bus. The fabric is mapped to the bus size according to the bit numbering of individual data bits. Bit numbering identifies the bit positions in a binary number, which may be from the most significant bit (MSB) to the least significant bit (LSB).

The memory access logic 430 comprises read/write address FIFOs (ADDR FIFOs) which store a sequence (or sequences) of memory address (or a plurality of memory addresses) generated by the read/write address logic (ADDR logic). As described above, the data allocator switch fabric 410 and the memory access logic 430 interact when the data is being transferred to and from the memory cells 400. Here, the access to memory cells 400 is granted, or data is transferred to or from the memory cells 400, when the address of a cell is present in the address sequence fetched from the FIFO.

All M bits of a word that have been transferred to or from the memory cells 400 are read and written in parallel. Addresses from the read/write FIFOs are fetched for all M bits. The addresses for each bit in the M-bit word are sent to the corresponding layer in the fabric according to the bit numbering of individual data bits. The fabric opens the link between the memory cell and the memory controller allowing data transfer to take place.

### Re-Ordering or Transposition and Processing of Multi-Bit Data

In an embodiment where data transposition occurs on words of multi-bit data (i.e. bits forming the word remain unchanged), where multi-bit data forms a word of width W-bits, and many words form a data string consisting of K words, memory blocks with a width W can be used. Each of the memory blocks are connected to the read data allocator and the write data allocator (or the data allocator switch) via a K×A address fabric (where A is the address of a row X in a memory block to store one word in the string) and a K×W data fabric. The address and data fabric are of high bandwidth. The fabric is mapped according to the bit numbering of individual words. Bit numbering identifies the word positions in a multi-word binary string, which may be from the most significant word (MSW) to the least significant word (LSW). The memory access logic 430 comprises read/write address FIFOs (ADDR FIFOs) which stores sequence (or sequences) of memory address (or addresses) generated by the read/write address logic (ADDR logic). As described above, the data allocator switch fabric 410 and the memory access logic 430 interact when the data is being transferred to and from the memory cells. Here, the access to memory cells 400 storing the word is granted, or data is transferred to or from the memory cells, when the address of the row or block is present in the address FIFO.

All K×W bits that have been transferred to or from the memory cells 400 are read and written in parallel. Addresses from the read/write FIFOs are fetched for all K words. The addresses for each word are sent to the corresponding layer in the address fabric according to the bit numbering of individual data words. The fabric opens the link between the row in the selected memory block and the memory controller allowing data transfer to take place.

### Memory Controller and Driver

The memory controller and driver 420 comprises controller and input/output (IO) buffers, read and write address decoders, sense amplifiers and write drivers. An address decoder is a binary decoder that has two or more inputs for address bits and one or more outputs for selection signals. The input to the read and write address decoders is the controller and IO buffers which comprise address bits and the output of the read and write address decoder are memory cell selection signals that go to the data allocator switch fabric 410 for selection of memory cells 410. The sense amplifiers input data to the controller and IO buffers, generally sensor amplifiers receive stored data signals from the memory cells and amplify them suitably such that the amplified values conform to recognizable logic levels and that the read-out data is interpreted correctly by the remainder of the digital circuit outside the memory. The write drivers send data to the memory cells via the write allocator switch fabric when single-bit data needs reordering or transposition; or directly to the row selected memory cells when multi-bits of data needs re-ordering or transposition. When single-bit data needs transposition, an in-memory ALU is integrated with the memory controller and driver circuit. When multi-bit data needs transposition, the ALU is integrated with the memory access logic, which allows arithmetic and logical operations on multi-bit words that are fetched from one or many memory blocks.

### Memory Access Logic

As previously described, the read and write access to the memory cells 400 are controlled by the memory access logic 430. The memory access logic is configured to be reprogrammed to generate different write and read allocations to remove conflicts and improve latency. The read and write access logics remove conflicts and improve latency. Both read and write logics consist of similar logic and circuits comprising read/write logic and read/write state machine controllers, read/write address logic, read/write address FIFOs, read/write counters and in-memory ALU.

The read/write logic is used to program and control the sequence and order in which memory cells are accessed to read/write data. During programming, the read/write logic may read the initial or start address of the memory cells to calculate an address of requested cells, and instructs the read/write address logic to generate address sequences in which access to the memory cells will occur. Read/write state machine controllers in the read/write logics are used to set/reset/read/write both data and sequence counters inside the memory access logic according to the read/write counters and status supplied by the read/write data bus. State machines are behaviour models that comprise the states that a system can be in to model how the system behaves. The different states of a system can be shown using a state machine. Sequence counters are present because the memory architecture depends on both the present input and the history of the input to generate address sequences. The state machine sends a read signal to the read/write FIFO to send the read/write address of the memory cells to the memory controller and drivers.

The read/write address logic generates a sequence of addresses in which memory will be read/written.

When single bits of a data word are re-ordered or transposed, each sequence of address comprises memory addresses of several memory cells, each corresponding to a bit in the data word. The addresses can be arranged according to the bit numbering of individual data bits. When multi-bit words are re-ordered or transposed, each sequence of address comprises memory addresses of several memory cells (FIG. 5B), or identifiers of the memory blocks and row addresses where data will be stored in the memory block (FIG. 6). The addresses will be arranged according to the word numbering of individual data words.

The read/write address FIFOs store the memory addresses generated by the read/write address logic. The memory addresses are read when they are triggered by the read/write logic and the read/write state machine controllers are sent to the memory controller drivers. Only the read/write address logic can write into the FIFOs. If the state-machine is programmed to repeat similar transpositions for multiple batches of data, then the FIFO read values are written back into FIFO, i.e. the read values are pushed to the back of the FIFO queue. This way the memory access logic is not required to generate the same addresses for every dataset. Reusing the addresses in the FIFOs speed up the access logic.

The read/write counters are used to synchronise the read/write address FIFO read values with the request made via the read/write bus. The data/values in the counters are set/reset depending on the access workflows programmed into the read/write logic and read/write state machine controllers.

The in-memory ALU is integrated with the memory controller and driver 420 when multi-bit data needs transposition.

### Memory Interface

The memory interface 440 to the memory 40 is the write and read data and control buses. The write and read data buses carry the information to and from the memory 40. The write and read control buses carry additional information such as, instructions for in-memory compute ALU logic; instructions for programming the access control logic (or the read/write logic) and state machines within the read/write state machine controllers; status controls (such as handshake signaling and access modes such as page or burst etc.) to configure the memory access logic; and read/write counters to synchronise with the read/write state machines. The status controls may be, but are not limited to, handshake signaling or access modes such as page or burst. Page and burst modes allow increased performance by supporting high speed data transfer.

### Specific Embodiments

In each of the embodiments shown in FIGS. 5A, 5B and 6, the black arrows show the flow of data, the grey arrows show the flow of addresses and the dotted arrows show the flow of instructions.

FIGS. 5A and 5B have the same configuration but the memory cells 501 in FIG. 5A are configured to store single bits of data and the memory cells 502 in FIG. 5B are configured to store multi-bit data. In other words, FIG. 5A shows an embodiment where the data is single bit words and FIG. 5B shows an embodiment where the data is multi-bit words that may be part of a string.

In the embodiment of FIGS. 5A and 5B, the data to and from memory cells 501, 502 is configured to flow into the data allocator switch fabric 410, in particular, the data is configured to flow from the memory cells 501, 502 into the read data allocator 511 and from the write data allocator 512 to the memory cells 501, 502. This is to connect the memory cells 501, 502 with the memory controller and driver circuit. The memory controller and driver 420 may comprise at least one of: controller and IO buffers 525, a read address decoder 521, a write address decoder 522, sense amplifiers 523 and write drivers 524. Data is configured to flow from the read data allocator 511 to the controller and IO buffers 525 and an in-memory ALU 539 of the memory access logic 430, preferably through the sense amplifiers 523. Data is then configured to flow from the controller and IO buffers 525 and the in-memory ALU 539 to the write data allocator 512, preferably through the write drivers 524. As described above, the data is configured to flow back into the memory cells 501, 502 from the write data allocator 512. Within that data flow, addresses are configured to flow from the controller and IO buffers 525 to the read and write address decoders 521, 522 and into the read and write data allocators 511, 512. Addresses are also configured to flow between the memory cells 501, 502 and the read and write address decoders 521, 522. The read and write data allocators 511, 512 may comprise row and column decoders. The read and write address decoders 521, 522 may comprise row and column decoders.

For this flow of data, data is configured to flow in and out of an interface of the memory circuit via a read data bus 541 and a write data bus 542. The data buses enable the flow of bit-wise data. The interface may also comprise a read control bus 543 and a write control bus 544 which carry at least one of instructions for the in-memory ALU 539, instructions for programming the read address logic 531, write address logic 532, the read logic state machine controller 533 and the write logic state machine controller 534 via a flow of data. The read and write address logic 531, 532 are configured to send read and write addresses to the controller and IO buffers 525 through read and write address FIFOs 535, 536. The controller IO buffers 525 may be configured to send address information back to the memory access logic, or more specifically, the read and write logic state machine controllers 533, 534. The interface, or more specifically, the read and write control buses 553, 554 may also carry status control information to the read and write logic state machine controllers 533, 534. Read and write counters in the read and write control buses 553, 554 and the read and write counters 537, 538 in the memory access logic help with synchronisation.

In the embodiment shown in FIG. 6, instead of memory cells 501, 502 as described with reference to FIGS. 5A and 5B, the memory has memory cells 602 inside memory blocks 654, configured to store multi-bit data slightly differently than the memory cells 502 of FIG. 5B. Like the data in the embodiment shown in FIG. 5B, the data in FIG. 6 can be multi-bit words that may be part of a string.

In FIG. 6, the data to and from each memory cell 602 is configured to flow into the column decoders in the read decoders 621. Each memory cell 602 is connected to the memory controller and driver 420. Each memory controller and driver 420 may comprise at least one of: controller and IO buffers 625, a read decoder 621, a write decoder 622, sense amplifiers 623 and write drivers 624. The data is configured to flow from each controller and IO buffers 625 into a read data allocator 611 through a fabric 613 and from a write data allocator 612 to each controller and IO buffers 625 through the fabric 613. This connects each memory cell 602 with the read and write data allocators 611, 612, a memory access logic 430 and a memory interface 440. The fabric 613 may be an address and data fabric, allowing both address and data to transfer into and from each memory cell 602. The fabric 613 is preferably configured to have a high bandwidth. The data flows into the memory cells 602 from controller and IO buffers 625 via the write drivers 624 and the column decoders in the write decoder 622. The data flows out of the memory cells 602 into the controller and IO buffers 625 via the column decoders in the read decoders 621 and the sense amplifiers 623. Data is then configured to flow from each controller and IO buffer 625 to the ALU 639 and to the write data allocator 612. Within that data flow, addresses are configured to flow into the controller and IO buffers 625 from the read and write data allocators 611, 612 through the fabric 613 and from the controller and IO buffers 625 to the read and write decoders 621, 622 through the fabric 613. Addresses may flow into the row decoder of the read and write decoders 621, 622 from the read and write data allocators 611, 612 through the fabric 613, thereby bypassing the flow between the read and write data allocators 611, 612 and the controller and IO buffers 625 through the fabric 613. Addresses are also configured to flow between each memory cell 602 and each read and write address decoder 621, 622 in each block, respectively. The read and write data allocators 611, 612 may comprise decoders, or more specifically, block and address decoders. The read and write decoders 621, 622 may comprise row and column decoders.

For this flow of data, data is configured to flow in and out of a memory interface 440 of the memory via a read data bus 641 and a write data bus 642. The data buses enable the flow of bit-wise data. The memory interface 440 may also comprise a read control bus 643 and a write control bus 644 which carry at least one of instructions for the ALU 639, instructions for programming the read address logic 631, write address logic 632, the read logic state machine controller 633 and the write logic state machine controller 634 via a flow of data. The read and write address logic 631, 632 are configured to send read and write addresses to the controller and IO buffers 621 through read and write address FIFOs 635, 636. The read and write address logic 631, 632 may send read and write addresses to the row decoders in the read and write decoders 621, 622 directly through read and write address FIFOs 635, 636. The controller IO buffers 625 may be configured to send address information from the fabric 613 back to the memory access logic 430, or more specifically, the read and write logic state machine controllers 633, 634. The memory interface 440, or more specifically, the read and write control buses 643, 644 may also carry status control information to the read and write logic state machine controllers 633, 634. Read and write counters in the read and write control buses 643, 644 and the read and write counters 637, 638 in the memory access logic help with synchronisation.

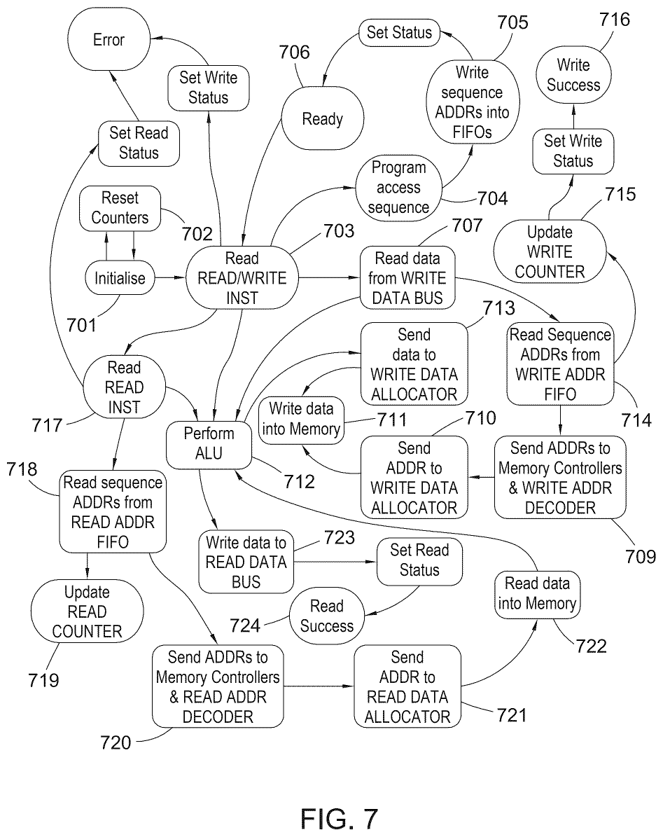

The method of any embodiments of the application, including the memory architectures in FIGS. 5A, 5B and 6 can be described using the state diagram in FIG. 7. Specifically, FIG. 7 describes a method comprising: generating, in a memory access logic, a write allocation that maps an input to memory cells of an array of memory cell in a first sequence and a read allocation that maps the memory cells of the array to an output in a second sequence; writing elements of data at the input to the array based on the write allocation; and reading elements of data stored in the array to the output based on the read allocation. A state diagram shows the various states of a system through transitions in the diagram and is used to show the functionality of a state machine.

The first step of the method is to initialise 701 the system. Initialising 701 the system comprises resetting 702 counters of the system. The memory interface 440, or more specifically, the read and write control buses, instructs 703 the read and write logic. The read and write logic is programmed 704 to generate read and write addresses which are stored 705 in read and write FIFOs so data storage and retrieval can occur, preferably in parallel. The status of the system changes to ready 706. Each time data is input or output to or from the memory cells, an address is written or read according to the read or write address FIFOs. The address can be written back to the read and write address FIFOs for use the next time data is input or output to or from the memory cells. This enables a ‘recycling’ of addresses. For example, an address is used to write data to the memory cells of the array during one clock cycle and the same address can be used to write data to the memory cells of the array during another clock cycle, until the read and write address FIFOs are instructed to not write data back to the read and write address FIFOs. After the state of the system is at ready, the read and write logic state machine controllers are able to respond to requests and instructions from the read and write control buses.

When a write instruction is carried through the write control bus, data is read 707 from the write data bus and flows to the ALU. If instructed by the write instruction from the write control bus, the ALU processes 712 the data and sends 713 it to the write data allocator through the write drivers. The write address location is provided 714 by the write address FIFO and the write counter is updated 715 by the write logic state machine controller. The write address location is sent 709 to the controller through the write address decoder and then sent 710 to the write data allocator. As the data from the ALU and the address are both sent to the write data allocator, the data is written 711 to the memory cells by the write data allocator. The write logic state machine controller may then send 716 an acknowledgement, or more specifically, a write success status, to the write control bus.

When a read instruction is carried 717 through the read control bus, the read address location is provided 718 by the read address FIFO and the read counter is updated 719 by the read logic state machine controller. The read address location is sent 720 to the controller, through the read address decoder and then sent 721 to the read data allocator switch. The data is read 722 from the memory cells by the read data allocator and sent to the ALU. The ALU processes 712 the data if instructed and sends it to the read data bus to write 723 the data to the read data bus or the write data allocator through the write logic state machine controller to write the data back to the memory cells. The read logic state machine controller may then send 724 an acknowledgement, or more specifically, a read success status, to the read control bus.

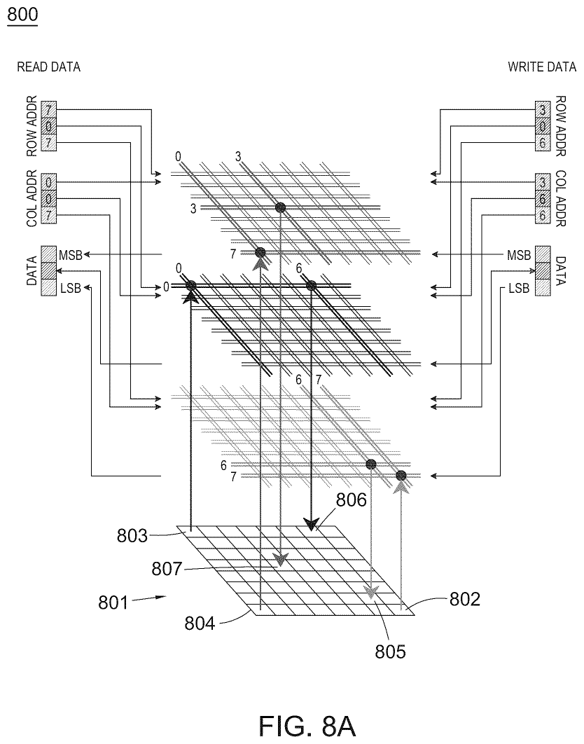

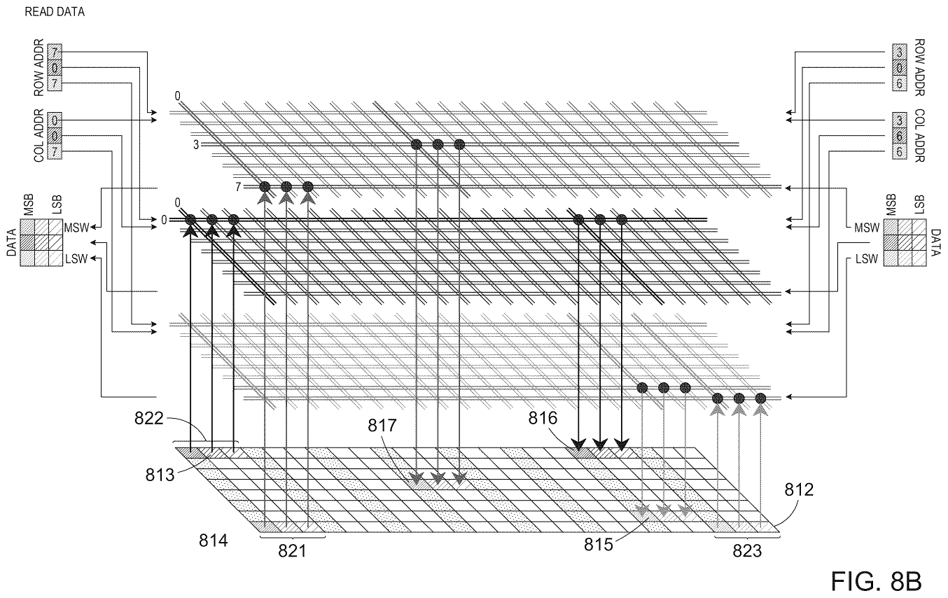

The embodiments of FIGS. 8A and 8B show the use of the allocator switch fabric, or allocator switch, or switch fabric, or fabric. The allocator switch fabric 800 of FIG. 8A is configured for single bit operation and the allocator switch fabric 810 of FIG. 8B is configured for multi-bit operation. In other words, the allocator switch fabric 800 of FIG. 8A permits of single bit data transmission and the allocator switch fabric 810 of FIG. 8B permits multi bit data transmission.

In each embodiment, the read and write data allocators, read or write data according to the position of the bits of data in the row and column addresses from the read and write address FIFOs. In FIGS. 8A and 8B, each bit or multi-bit word is given a colour according to the significance of the bit. For example, blue is the most significant bit or word, and red is the least significant bit or word.

In FIG. 8A, the width of the allocator switch fabric 800 is M×B, where M is the number of bits in a single data set and B is the bit-length, which will always be 1 because FIG. 8A deals with single bits, i.e. B=1. In this example, the number of bits is 3, i.e. M=3. The allocator switch fabric reads or writes data to the array of memory cells 801 according to the position of the bit in the dataset so that the most significant bit (MSB), least significant bit (LSB) and all the other bits within the dataset are read from or written to different memory cells. The array of memory cells 801 are provided in bit-sized units so each bit is written to or read from a different memory cell. A write allocation generated by memory access logic 430 maps an input to respective a first subset of the memory cells 801 of the array in a first subset order, and the read allocation reads a second subset of the memory cells to the output in a second subset order. The input and output in this embodiment are single-bit data, or single-bit words. The read allocator comprises row address, column address and data. The MSB is read from coordinate (7, 0) of a first memory cell 804 in the array of memory cells 801, the adjacent bit is read from coordinate (0, 0) of a second memory cell 803 in the array of memory cells 801 and the LSB is read from coordinate (7, 7) of a third memory cell 802 in the array of memory cells 801. The write allocator comprises row address, column address and data. The MSB is written to coordinate (3, 3) of fourth memory cell 807 in the array of memory cells 801, the adjacent bit is read from coordinate (0, 6) of a fifth memory cell 806 in the array of memory cells 801 and the LSB is read from coordinate (6, 6) of a sixth memory cell 805 in the array of memory cells 801.

Turning to FIG. 8B, the width of the allocator switch fabric 810 is M×B, where M is the number of words in a single data set and B is the bit-length of each word. In this example, the number of words is 3, i.e. M=3; and the bit-length of each word is 3, i.e. B=3. The allocator switch fabric reads or writes data to the array of memory cells 811 according to the position of the word in the string so the most significant word (MSW), least significant word (LSW) and all the other words within the string are read from or written to different memory cells. The memory cells 811 are provided in word-sized units so each word can be written to or read from a different memory cell (or a different subset of memory cells) without transposition. A described above, a write allocation generated by memory access logic 430 maps an input to respective first subsets of the memory cells 811 of the array in a first subset order, and the read allocation reads respective second subsets of the memory cells to the output in a second subset order. Each of the memory cells in each of the first subsets are adjacent such that the input is mapped to respective adjacent memory cells in each first subset, and each of the memory cells in each of the second subsets are adjacent such that the output is read from adjacent memory cells in each second subset of the array. The read allocator comprises row address, column address and data. The MSW is read from of a first memory cells 814 of a first one of the second subsets 821, the adjacent word (e.g. adjacent in the data stream) is read from second memory cells 813 of a second one of the second subsets 822 and the LSW is read from third memory cells 812 of a third one of the second subsets 823. The write allocator comprises row address, column address and data. The MSW is written to fourth memory cells 817 in a first one of the first subsets, the adjacent word is read from fifth memory cells 816 in a second one of the first subsets, and the LSW is read from sixth memory cells 815 in a third one of the first subsets. The address in the column decoder of the read allocator may contain the address of either the MSB or the LSB, and the width of the multi-bit data. This enables relative addressing thereby permitting access to the adjacent memory cells storing the word data from just a single address.

The first, second and third ones of the first subsets of the memory cells 811 of the array are in a first subset order, where the first subset order has the coordinates (7, 0), (0, 0) and (7, 7). The first, second and third ones of the first subsets each comprise a respective first arrangement of memory cells 811 of the array, having coordinates (7, 0), (0, 0) and (7, 7). The first, second and third ones of the second subsets of the memory cells 811 of the array are in a second subset order, where the second subset order has the coordinates (3, 3), (0, 6) and (6, 6). The first, second and third ones of the second subsets each comprise a respective second arrangement of memory cells 811 of the array, having coordinates (3, 3), (0, 6) and (6, 6). Each of the respective first arrangements are different to each of the respective second arrangements.

The described embodiments are provided for illustration purposes and are not intended to be limiting. As the skilled person will understand, various modifications can be made to the embodiments. The invention is defined by the scope of the appended claims.

Also described herein are the following numbered embodiments:

Embodiment 1. A memory comprising:

an array of memory cells;

a memory access logic programmable to generate a write allocation that maps an input comprising elements of data in a first sequence to the memory cells of the array and a read allocation that maps the memory cells of the array to an output comprising elements of data in a second sequence; and

a memory controller arranged to write the elements of data at the input to the array based on the write allocation and to read the elements of data stored in the array to the output based on the read allocation.

Embodiment 2. The memory of embodiment 1, wherein the first sequence is different to the second sequence such that a first sequence order of the elements of data at the input is different to a second sequence order of the elements of data at the output.
Embodiment 3. The memory of embodiment 1 or embodiment 2, wherein the input is a parallel input of a first width and the output is a parallel output of a second width, preferably wherein the first and second widths are the same.
Embodiment 4. The memory of any preceding embodiment, wherein the memory access logic is configured to be reprogrammed to generate different write and read allocations.
Embodiment 5. The memory of any preceding embodiment, wherein the elements of data at the input and output are one of: single bits of a data word or multi-bit words of a data string.
Embodiment 6. The memory of embodiment 5, wherein the most significant to least significant bit or word of each single bit or multi-bit word is mapped to the input or read to the output in parallel.
Embodiment 7. The memory of any preceding embodiment, wherein the write allocation maps the input to respective first subsets of the memory cells of the array in a first subset order, and the read allocation reads respective second subsets of the memory cells to the output in a second subset order.
Embodiment 8. The memory of embodiment 7, wherein the first subsets each comprise a respective first arrangement of memory cells of the array and the second subsets each comprise a respective second arrangement of memory cells of the array.
Embodiment 9. The memory of embodiment 8, wherein each of the respective first arrangements are different to each of the respective second arrangements.
Embodiment 10. The memory of embodiment 8 or embodiment 9, wherein the first arrangements each have a width equal to a/the first width of the input and a/the second width of the output.
Embodiment 11. The memory of embodiment 8 or embodiment 9, wherein the first and second arrangements each have a width equal to a/the first width of the input and a/the second width of the output.
Embodiment 12. The memory of any of embodiments 7-11, wherein the first subset order is different to the second subset order.
Embodiment 13. The memory of any of embodiments 7-12, wherein each of the first subsets comprise a row or a column of the memory cells of the array.

Embodiment 14. The memory of any of embodiments 7-13, wherein each of the second subsets comprise a row or a column of the memory cells of the array.

Embodiment 15. The memory of any of embodiments 7-14, wherein each of the first subsets of the memory cells of the array are adjacent such that the input is mapped to respective first subsets of adjacent memory cells of the array, and each of the second subsets of the memory cells of the array are adjacent such that the output is read from respective second subsets of adjacent memory cells of the array.
Embodiment 16. The memory of any of embodiments 7-15 when dependent on embodiment 5, wherein each single bit or multi-bit word is mapped to respective first subsets of adjacent memory cells of the array, and each single bit or multi-bit word is read to the output from respective second subsets of adjacent memory cells of the array.
Embodiment 17. The memory of any of embodiments 7-14, wherein the second subset order of the memory cells of the array read to the output is a predetermined shift of the first subset order of the memory cells of the array.
Embodiment 18. The memory of any of embodiments 7-14, wherein the second subset order of the memory cells of the array read to the output is a rotation of the first subset order of the memory cells of the array.
Embodiment 19. The memory of any of embodiments 7-12, wherein the first subset order is a butterfly transposition of the elements of data at the input.
Embodiment 20. The memory of any of embodiments 7-19, wherein each respective first subset of the memory cells of the array and each respective second subset of the memory cells of the array both comprise at least one single bit from each data word or at least one multi-bit word from each data string at the input.
Embodiment 21. The memory of embodiment 15 or embodiment 19, when dependent on embodiment 13, wherein each row or column of the memory cells of the array of the first subset comprises a plurality of multi-bit words of one data string of a plurality of data strings at the input, and wherein each respective second subset of the memory cells of the array comprises at least one multi-bit word from each data string of the plurality of data strings at the input.
Embodiment 22. The memory of any preceding embodiment, wherein the memory access logic comprises a read logic and a write logic, wherein the read logic generates the read allocation and the write logic generates the write allocation.
Embodiment 23. The memory of any preceding embodiment, wherein the memory access logic comprises:

a read state controller; and

a write state controller.

Embodiment 24. The memory of any preceding embodiment, further comprising a memory interface configured to transfer the elements of data at the input to the memory cells of the array and to transfer the elements of data stored in the memory cells of the array to the output.
Embodiment 25. The memory of embodiment 24, wherein the memory interface comprises a read data bus, and a write data bus, wherein read and write data buses are configured to transfer instructions for programming the memory access logic to the memory access logic.
Embodiment 26. The memory of embodiments 24 or embodiment 25, wherein the read and write data buses are further configured to supply the memory access logic with a read counter, a write counter and a status control.
Embodiment 27. The memory of embodiment 26 when dependent on embodiment 23,

wherein the read and write state controllers configured to use the read and write counters and the status to set, reset, read or write both data and sequence counters within the memory access logic.

Embodiment 28. The memory of any preceding embodiment, further comprising a data allocator switch fabric configured to connect the memory cells with the memory access logic and the memory controller.
Embodiment 29. The memory of embodiment 28, wherein the data allocator switch fabric comprises a switch fabric, a read data allocator and a write data allocator, wherein the read and write data allocators are configured to decode an address of the array corresponding to the read allocation or the write allocation.
Embodiment 30. The memory of embodiments 28 or embodiment 29, wherein the switch fabric is mapped to the bus size according to the bit numbering of individual data.
Embodiment 31. The memory of any preceding embodiment, wherein the memory cells of the array are divided into a first memory cell subgroup and a second memory cell subgroup;
the input comprises a first input frame and a second input frame;
the first input frame comprises a first data element and second data element;
the second input frame comprises a third data element and a fourth data element; and
the write allocation maps:

the first data element to a first memory cell in the first memory cell subgroup;

the second data element to first memory cell in the second memory cell subgroup;

the third data element to a second memory cell of the first memory cell subgroup; and

the fourth data element to a second memory cell of the second memory cell subgroup;

Embodiment 32. The memory of embodiment 31, wherein a transformational relationship between the location of the first memory cell and second memory cell in the first memory cell subgroup corresponds to or is identical to a transformational relationship between the location of the first memory cell and second memory cell in the second memory cell subgroup.
Embodiment 33. The memory of embodiment 32, wherein the transformational relationship is a translational or a rotational relationship, optionally wherein the transformational relationship is to rotate or translate by a single memory cell from one memory cell to an adjacent memory cell.
Embodiment 34. The memory of any of embodiments 31-33, wherein the order of the first data element in the first input frame corresponds with the order of the third data element in the second input frame, and the order of the second data element in the first input frame corresponds with the order of the fourth data element in the second input frame.
Embodiment 35. The memory of any of embodiments 31-34, wherein the read allocation maps the memory cells of the array to an output comprising a first output frame comprising the first data element and the third data element and a second output frame comprising the second data element and the fourth data element.
Embodiment 36. The memory of embodiment 35, wherein the order of the first data element in the first output frame corresponds with the order of the second data element in the second output frame.
Embodiment 37. The memory of any of embodiments 35 or 36, wherein the order of the third data element in the first output frame corresponds with the order of the fourth data element in the second output frame.
Embodiment 38. The memory of any of embodiments 31-37, wherein the first input frame and second input frame each include data corresponding to detected light intensity values at an output plane of an optical Fourier transform stage.
Embodiment 39. The memory of any of embodiments 31-38, wherein each of the first and second data elements corresponds to a detected light intensity value at a port in an array of ports at an output plane of an optical Fourier transform stage, and wherein each of the third and fourth data elements corresponds to a detected light intensity value at a port in an array of ports at an output plane of the same or another optical Fourier transform stage.
Embodiment 40. The memory of embodiment 39, wherein the relative order of the first and second data elements in the first input frame and the relative order of the third and fourth data elements in the second input frame each correspond to a relative position of ports in an array of ports at an output plane in the respective optical Fourier transformation stage, optionally wherein the relative order is adjacent or subsequent positions in an order and the relative position is an adjacent position in the array of ports.
Embodiment 41. The memory of any of embodiment 31-40, wherein the first data element corresponds to a first detected intensity at a first port in an array of ports at an output plane of an optical Fourier transform stage and the third data element corresponds to a second detected intensity at the first port, and
optionally wherein the second data element corresponds to a third detected intensity at a second port in the array of ports and the fourth data element corresponds to a fourth detected intensity at the second port.
Embodiment 42. A method comprising:

generating, in a memory access logic, a write allocation that maps an input to memory cells of an array of memory cell in a first sequence and a read allocation that maps the memory cells of the array to an output in a second sequence;

writing elements of data at the input to the array based on the write allocation; and

reading elements of data stored in the array to the output based on the read allocation.

Embodiment 43. A method including carrying out any of the steps carried out by the memory and the components of the memory described in any of embodiments 1-41.

1. A memory comprising:
an array of memory cells;
a memory access logic programmable to generate a write allocation that maps an input comprising elements of data in a first sequence to the memory cells of the array and a read allocation that maps the memory cells of the array to an output comprising elements of data in a second sequence; and
a memory controller arranged to write the elements of data at the input to the array based on the write allocation and to read the elements of data stored in the array to the output based on the read allocation.

2. The memory of claim 1, wherein the first sequence is different to the second sequence such that a first sequence order of the elements of data at the input is different to a second sequence order of the elements of data at the output.

3. The memory of claim 1, wherein the input is a parallel input of a first width and the output is a parallel output of a second width, wherein the first and second widths are the same.

4. (canceled)

5. The memory of claim 1, wherein the elements of data at the input and output are one of:
single bits of a data word or multi-bit words of a data string.

6. The memory of claim 5, wherein the most significant to least significant bit or word of each single bit or multi-bit word is mapped to the input or read to the output in parallel.

7. The memory of claim 1, wherein the write allocation maps the input to respective first subsets of the memory cells of the array in a first subset order, and the read allocation reads respective second subsets of the memory cells to the output in a second subset order.

8. The memory of claim 7, wherein the first subsets each comprise a respective first arrangement of memory cells of the array and the second subsets each comprise a respective second arrangement of memory cells of the array.

9. The memory of claim 8, wherein each of the respective first arrangements are different to each of the respective second arrangements.

10. The memory of claim 8, wherein the first arrangements each have a width equal to a first width of the input and a second width of the output.

11. The memory of claim 8, wherein the first and second arrangements each have a width equal to a first width of the input and a second width of the output.

12. The memory of claim 7, wherein the first subset order is different to the second subset order.

13. The memory of claim 7, wherein each of the first subsets comprises a row or a column of the memory cells of the array.

14. The memory of claim 7, wherein each of the second subsets comprises a row or a column of the memory cells of the array.

15. The memory of claim 7, wherein each of the first subsets of the memory cells of the array are adjacent such that the input is mapped to respective first subsets of adjacent memory cells of the array, and each of the second subsets of the memory cells of the array are adjacent such that the output is read from respective second subsets of adjacent memory cells of the array.

16. The memory of claim 7, wherein the elements of data at the input and output are one of single bits of a data word or multi-bit words of a data string, and wherein each single bit or multi-bit word is mapped to respective first subsets of adjacent memory cells of the array, and each single bit or multi-bit word is read to the output from respective second subsets of adjacent memory cells of the array.

17. The memory of claim 7, wherein the second subset order of the memory cells of the array read to the output is a predetermined shift of the first subset order of the memory cells of the array.

18. (canceled)

19. The memory of claim 7, wherein the first subset order is a butterfly transposition of the elements of data at the input.

20. The memory of claim 7, wherein each respective first subset of the memory cells of the array and each respective second subset of the memory cells of the array both comprise at least one single bit from each data word or at least one multi-bit word from each data string at the input.

21. The memory of claim 15, wherein each of the first subsets comprises a row or a column of the memory cells of the array, wherein each row or column of the memory cells of the array of the first subset comprises a plurality of multi-bit words of one data string of a plurality of data strings at the input, and wherein each respective second subset of the memory cells of the array comprises at least one multi-bit word from each data string of the plurality of data strings at the input.

22-30. (canceled)

31. The memory of claim 1, wherein the memory cells of the array are divided into a first memory cell subgroup and a second memory cell subgroup;
the input comprises a first input frame and a second input frame;
the first input frame comprises a first data element and second data element;
the second input frame comprises a third data element and a fourth data element; and
the write allocation maps:
the first data element to a first memory cell in the first memory cell subgroup;
the second data element to first memory cell in the second memory cell subgroup;
the third data element to a second memory cell of the first memory cell subgroup; and
the fourth data element to a second memory cell of the second memory cell subgroup.

32. The memory of claim 31, wherein a transformational relationship between the location of the first memory cell and second memory cell in the first memory cell subgroup corresponds to or is identical to a transformational relationship between the location of the first memory cell and second memory cell in the second memory cell subgroup.

33. The memory of claim 32, wherein the transformational relationship is a translational or a rotational relationship, and wherein the transformational relationship is to rotate or translate by a single memory cell from one memory cell to an adjacent memory cell.

34. The memory of claim 31, wherein an order of the first data element in the first input frame corresponds with an order of the third data element in the second input frame, and an order of the second data element in the first input frame corresponds with an order of the fourth data element in the second input frame.

35. The memory of claim 31, wherein the read allocation maps the memory cells of the array to an output comprising a first output frame comprising the first data element and the third data element and a second output frame comprising the second data element and the fourth data element.

36. The memory of claim 35, wherein an order of the first data element in the first output frame corresponds with an order of the second data element in the second output frame.

37. The memory of claim 35, wherein an order of the third data element in the first output frame corresponds with an order of the fourth data element in the second output frame.

38. The memory of claim 31, wherein the first input frame and second input frame each include data corresponding to detected light intensity values at an output plane of an optical Fourier transform stage.

39. The memory of claim 31, wherein each of the first and second data elements corresponds to a detected light intensity value at a port in an array of ports at an output plane of an optical Fourier transform stage, and wherein each of the third and fourth data elements corresponds to a detected light intensity value at a port in an array of ports at an output plane of the same or another optical Fourier transform stage.

40. The memory of claim 39, wherein a relative order of the first and second data elements in the first input frame and a relative order of the third and fourth data elements in the second input frame each correspond to a relative position of ports in an array of ports at an output plane in the respective optical Fourier transformation stage, and wherein the relative order is adjacent or subsequent positions in an order and the relative position is an adjacent position in the array of ports.

41. The memory of claim 31, wherein the first data element corresponds to a first detected intensity at a first port in an array of ports at an output plane of an optical Fourier transform stage and the third data element corresponds to a second detected intensity at the first port, and wherein the second data element corresponds to a third detected intensity at a second port in the array of ports and the fourth data element corresponds to a fourth detected intensity at the second port.

42. A method comprising:
generating, in a memory access logic, a write allocation that maps an input to memory cells of an array of memory cell in a first sequence and a read allocation that maps the memory cells of the array to an output in a second sequence;
writing elements of data at the input to the array based on the write allocation; and
reading elements of data stored in the array to the output based on the read allocation.
